(19) United States
(12) Patent Application Publication
(10) Pub. No.: US 2013/0075844 A1
(43) Pub. Date: Mar. 28, 2013

(54) SEMICONDUCTOR DEVICE AND MANUFACTURING METHOD THEREOF

(71) Applicants: Kiyotaka Miyano, Tokyo (JP); Tomonori Aoyama, Yokohama-shi (JP)

(72) Inventors: Kiyotaka Miyano, Tokyo (JP); Tomonori Aoyama, Yokohama-shi (JP)

(21) Appl. No.: 13/546,379

(22) Filed: Jul. 11, 2012

(30) Foreign Application Priority Data
Sep. 26, 2011 (JP) 2011-209373

(51) Int. Cl. H01L 21/02; H01L 29/82

(52) U.S. Cl. 257/421; 438/3; 257/E29.323; 257/E21.002

(57) ABSTRACT

A semiconductor device according to the present embodiment comprises a lower electrode provided above a semiconductor substrate and made of metal, an upper electrode provided above the lower electrode and made of metal, and a crystal layer provided between the lower electrode and the upper electrode. A thickness of each of the lower electrode and the upper electrode is smaller than a thickness of a skin layer deriving from a skin effect corresponding to a frequency of a microwave used to crystallize the crystal layer.

### CROSS REFERENCE TO RELATED APPLICATIONS

This application is based upon and claims the benefit of priority from the prior Japanese Patent Application No. 2011-209373, filed on Sep. 26, 2011, the entire contents of which are incorporated herein by reference.

### FIELD

The embodiments of the present invention relate to a semiconductor device and manufacturing method thereof.

### BACKGROUND

A ReRAM (Resistance Change Random Access Memory), for example, has been developed as a resistance change memory. In the ReRAM, a cross-point cell array can be easily configured and the cell array can be easily formed into a three-dimensional stacked structure. Therefore, the ReRAM is suited for downscaling.

This type of ReRAM includes selector elements (diode selectors) so as to carry a current to each variable resistive element. Each selector element is configured into a PIN (P-type/I-type/N-type) type structure, an NIP (N-type/I-type/P-type) type structure or the like so as to obtain rectifying characteristics.

In order to form such a selector element, impurity-based amorphous silicon, amorphous silicon in an intrinsic state, and impurity-based amorphous silicon are deposited on a lower electrode in this order. Furthermore, an upper electrode is deposited on the deposited silicons mentioned above. Thereafter, the amorphous silicons are annealed by RTA (Rapid Thermal Annealing). In this case, the RTA crystallizes the amorphous silicons into polysilicons or single-crystal silicons using the metal of the electrodes as a seed, and at the same time, activates the impurities in the silicons.

However, high-temperature annealing such as RTA has the following problems. That is, when high-temperature annealing is performed, impurities are diffused too widely, no intrinsic region remains, and then the selector element cannot be formed into a desired PIN or NIP structure. That is, there is a problem that it is difficult to obtain desired element characteristics by the high-temperature annealing.

There is also known an MRAM (Magnetic Random Access Memory) as one type of resistance change memories. Each memory cell in an MRAM includes an MTJ (Magnetic Tunnel Junction) element. The MTJ element that uses the TMR (Tunneling Magnetoresistive) effect has a stacked structure in which two ferromagnetic layers sandwich a nonmagnetic layer (a tunnel barrier layer) therebetween.

The MTJ element is sandwiched between an upper electrode and a lower electrode that are made of metal and the MTJ element itself is low in a heat resistance. Accordingly, the use of high-temperature annealing for crystallizing a tunnel barrier layer may possibly degrade the characteristics of the MTJ element.

### BRIEF DESCRIPTION OF THE DRAWINGS

FIG. 1 is a block diagram showing a configuration of a ReRAM according to a first embodiment;

FIG. 2 is a plan view of a memory cell array 1;

FIG. 3 is a perspective view of a memory cell array 1;

FIG. 4 is a cross-sectional view showing a configuration of each memory cell 13;

FIG. 5 is a cross-sectional view showing a configuration of the selector element SD;

FIGS. 6A to 6C are cross-sectional views showing the method of manufacturing the selector element SD in the ReRAM according to the first embodiment;

FIG. 7 is a block diagram showing a configuration of an MRAM according to a second embodiment;

FIG. 8 is an explanatory diagram showing a data writing operation for writing data to one memory cell MC;

FIG. 9 is a cross-sectional view showing a configuration of the MTJ element; and

FIGS. 10A to 10C are cross-sectional views showing the method of manufacturing the MRAM according to the second embodiment.

### DETAILED DESCRIPTION

A semiconductor device according to the present embodiment comprises a lower electrode provided above a semiconductor substrate and made of metal, an upper electrode provided above the lower electrode and made of metal, and a crystal layer provided between the lower electrode and the upper electrode. A thickness of each of the lower electrode and the upper electrode is smaller than a thickness of a skin layer deriving from a skin effect corresponding to a frequency of a microwave used to crystallize the crystal layer.

Embodiments will now be explained with reference to the accompanying drawings. The present invention is not limited to the embodiments.

### First Embodiment: ReRAM

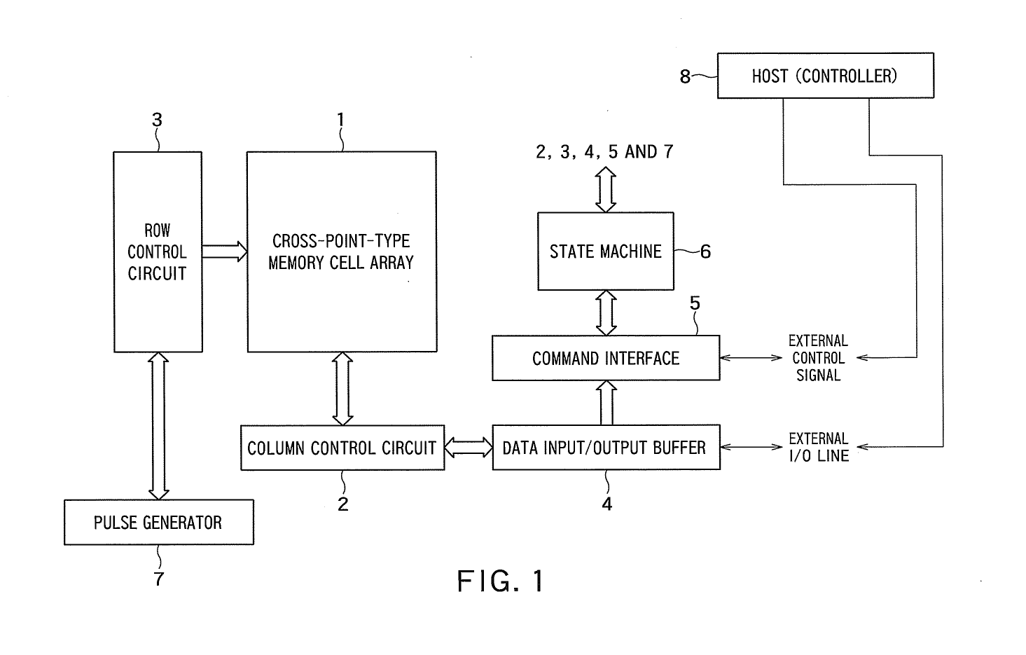

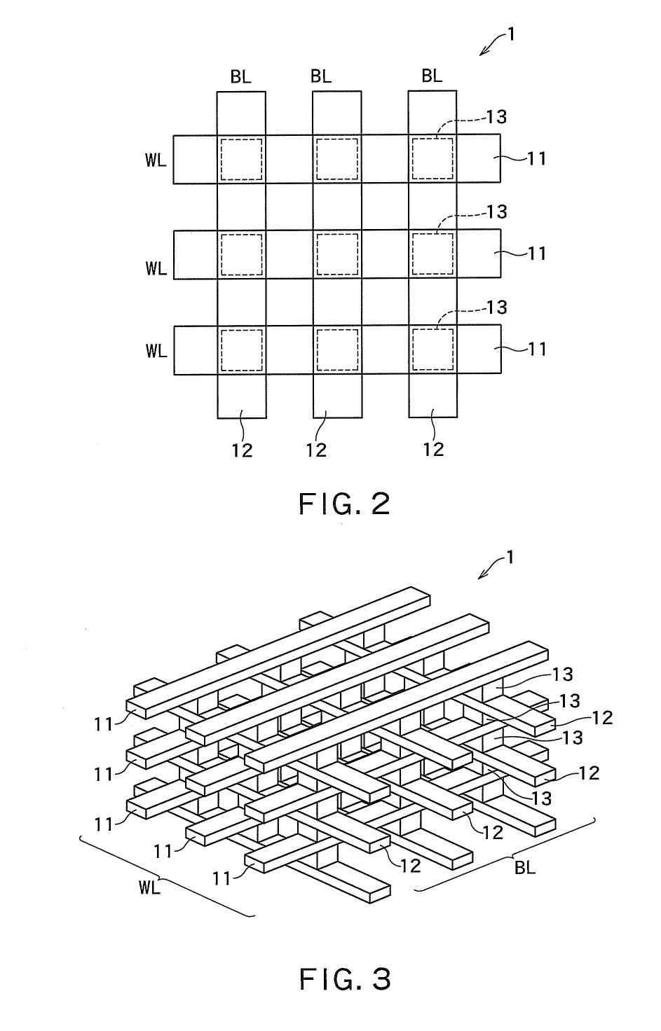

FIG. 1 is a block diagram showing a configuration of a ReRAM according to a first embodiment. A memory cell array 1 is a cross-point cell array as shown in a plan view of FIG. 2 and a perspective view of FIG. 3. Memory cells 13 are arranged at cross-points between word lines (WL) 11 and bit lines (BL) 12 crossing one another, respectively. FIG. 3 shows that the cell array 1 is configured as a three-dimensional cell array in which four layers of memory cells 13 are stacked.

A column control circuit 2 and a row control circuit 3 select and control the bit lines 12 and the word lines 11, respectively, for data erasing, data writing, and data reading with respect to the memory cell array 1.

A data input/output buffer 4 receives write data, receives an erase instruction, outputs read data, and receives address data and command data. The memory cell array 1 transmits and receives data to and from an external host 8 via the data input/output buffer 4 and an I/O line. A column control circuit 2 loads the received write data to use the data for write control over the memory cell array 1. The column control circuit 2 latches the data read from the memory cell array 1 and outputs the read data to the host 8 via the data input/output buffer 4.

The address data for selecting a memory cell 13 is transmitted from the data input/output buffer 4 to the column control circuit 2 or the row control circuit 3 via a state machine 6. The command data from the host 8 is transmitted from the data input/output buffer 4 to a command interface 5.

The command interface 5 determines whether the data input to the data input/output buffer 4 is write data, command data, or address data in response to a control signal transmitted from the host 8. When the data input to the data input/output buffer 4 is the command data, the command interface 5 decodes the command data and transfers the command data to the state machine 6 as a command signal.

The state machine 6 manages the entirety of the ReRAM. That is, the state machine 6 controls reading, writing, erasing, data input/output and the like in response to commands from the host 8.

A pulse generator 7 generates a control pulse for an arbitrary voltage at an arbitrary timing under control of the state machine 6. The control pulse is transferred to one word line 11 selected by the row control circuit 3 as a write pulse, a read pulse or the like.

The peripheral circuit elements 2 to 8 of the memory cell array 1 can be formed right under the memory cell array 1. This can make a chip area of the ReRAM substantially equal to an area of the memory cell array 1.

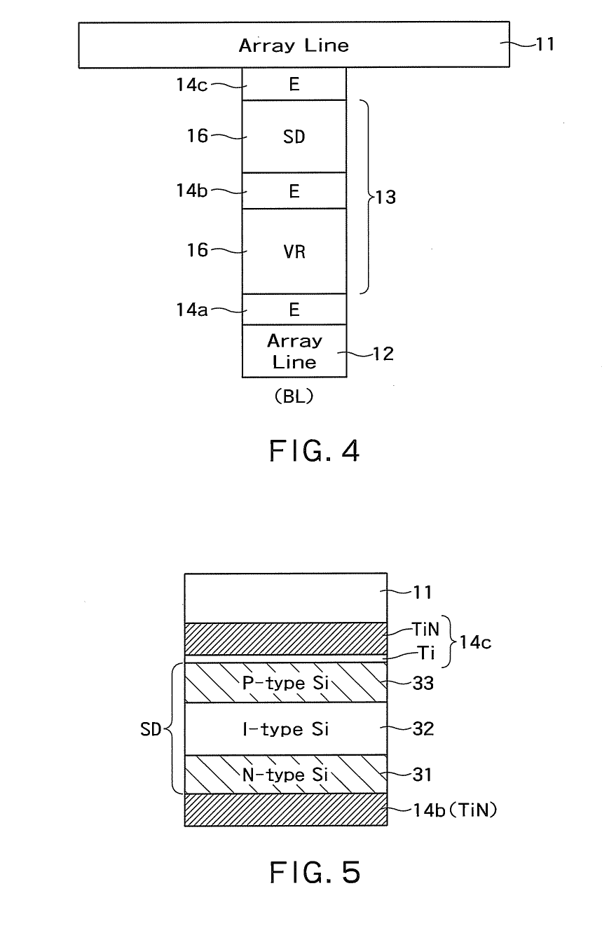

FIG. 4 is a cross-sectional view showing a configuration of each memory cell 13. The memory cell 13 includes a variable resistive element VR and a selector element SD. The resistance of the variable resistive element VR is variably set by voltage, current, heat, or chemical energy. The selector element SD is used to carry a current to the variable resistive element VR of the selected memory cell 13. The selector element SD is stacked on the variable resistive element VR via an electrode 14b.

Electrodes 14a and 14c are provided between the variable resistive element VR and one bit line 12 and between the selector element SD and one word line 11, respectively. The electrodes 14a, 14b, and 14c function as adhesive layers and barrier metal. To this end, the electrodes 14a, 14b, and 14c are formed out of a metal material such as W, Pt, Au, Ag, TiAlN, SrRuO, Ru, RuN, Ir, Co, Ti, TiN, TaN, LaNiO, Al, PtIrOx, PtRhOx, Rh, or TaAlN.

The word lines 11 and the bit lines 12 are low-resistance metal wires made of tungsten (W), tungsten silicide (WSi), nickel silicide (NiSi), or cobalt silicide (CoSi), for example.

FIG. 5 is a cross-sectional view showing a configuration of the selector element SD. The selector element SD includes an N-type silicon crystal layer 31, an intrinsic (I-type) silicon crystal layer 32, and a P-type silicon crystal layer 33, and constitutes a PIN diode or an NIP diode, for example. The silicon layers 31 to 33 are made of polysilicon or single crystal silicon.

The selector element SD is provided on the electrode 14b serving as a lower electrode (hereinafter, also “lower electrode 14b”). In the first embodiment, the lower electrode 14b is made of titanium nitride (TiN). The electrode 14c serving as an upper electrode (hereinafter, also “upper electrode 14c”) is provided on the selector element SD. In the first embodiment, the upper electrode 14c is made of titanium (Ti) and titanium nitride (TiN). The metal wire (the word line WL) 11 is provided on the upper electrode 14c as described with reference to FIG. 4. The selector element SD as well as the variable resistive element VR is provided above a silicon substrate (not shown).

A thickness δ of each of the lower electrode 14b and the upper electrode 14c is smaller than a thickness δₛ of a skin layer deriving from a skin effect corresponding to a frequency of microwaves used in a microwave annealing step to be described later (δ≦δₛ). This is a condition in which the microwaves can pass through the lower electrode 14b and the upper electrode 14c and reach the selector element SD present between the lower and upper electrodes 14b and 14c.

More specifically, the thickness δₛ of the skin layer is determined by the following Equation 1.

δₛ=sqrt(2/ωμσ) (Equation 1)

In this equation, ω(=2πf) represents an angular frequency of the microwaves, μ represents a magnetic permeability of the metal constituting the lower and upper electrodes 14b and 14c, and σ represents an electric conductivity of the metal constituting the lower and upper electrodes 14b and 14c. Further, “sqrt” represents a square root.

When a plurality of metal materials (Ti and TiN) constitute an electrode such as the upper electrode 14c, each of the metal materials constituting the upper electrode 14c is formed to have a thickness smaller than the thickness of the skin layer of the metal material (Ti or TiN). In general terms, thicknesses δ₁ to δₙ of a plurality of metal materials M1 to Mn (where n is an integer), respectively constituting the upper or lower electrode of the selector element SD need to satisfy the following Equation 2.

sqrt(ωμ₁σ₁/2)×δ₁+sqrt(ωμ₂σ₂/2)×δ₂+ . . . sqrt(ωμₙσₙ/2)×δₙ≦1 (Equation 2)

In this equation, μ₁ to μₙ represent the magnetic permeability of the metal materials M1 to Mn and σ₁ to σₙ represent the electric conductivity of the metal materials M1 to Mn, respectively.

By using the lower electrode 14b and the upper electrode 14c that satisfy the Equation 2, the microwaves can reach the silicons, which is to become the silicon crystal layers 31 to 33 later, in the selector element SD. The microwaves can also crystallize the silicons in the selector element SD and activate the impurities contained in the silicons.

An annealing step in a process of manufacturing a semiconductor device is as indispensable to improving the crystallinity of the semiconductor device, activating dopants, and the like as before. The annealing step has been regarded as an important technique in the semiconductor industry.

However, long-time annealing disadvantageously degrades the concentration profile of the impurity and deviates various interface characteristics from designed values. This is why the RTA method or the like is recently used as an annealing method that can perform annealing at a very high temperature in a short time. The annealing method for performing annealing at such a high temperature in such a short time can improve the crystallinity and activate dopants while suppressing defects that possibly accompany the long-time annealing.

Nevertheless, it is difficult to locally implant the impurity and form a desired concentration profile of the impurity because such high-temperature annealing results in the wide diffusion of the impurity. For example, in a case of crystallizing the amorphous silicons in the selector element SD into the silicon crystal layers 31 to 33 with the electrodes 14b and 14c made of the metal used as a seed, the impurities diffuse into the silicon layer 32 in an intrinsic state when the high-temperature annealing such as the RTA is performed. Therefore, it is difficult to form a PIN diode or an NIP diode by the high-temperature annealing such as the RTA.

Therefore, in the first embodiment, the microwave annealing is performed to form the PIN diode or the NIP diode having desired concentration profiles as each selector element SD. The microwave annealing can sufficiently improve the crystallinity and activate the impurities even at a low temperature (200 degrees to 550 degrees).

Microwaves are absorbed efficiently by an amorphous material and not so efficiently by a single crystal material due to the characteristics of the microwaves. Accordingly, amorphous silicons are deposited first at a time of forming the silicon crystal layers 31 to 33, and the microwaves are then irradiated onto these amorphous silicons, thereby crystallizing the amorphous silicons into polysilicons or single crystal silicons.

To crystallize the amorphous silicons into the polysilicon or single crystal silicons, the electrodes 14b and 14c made of the metal are necessary to use as a seed. The amorphous silicons are crystallized into the polysilicons or single crystal silicons using the electrodes 14b and 14c as the seed.

On the other hand, when the electrodes 14b and 14c are too thick, the electrodes 14b and 14c shield the microwaves because the electrodes 14b and 14c are made of the metal. In this case, the microwaves cannot reach the amorphous silicons present between the electrodes 14b and 14c. Therefore, each of the thicknesses of the electrodes 14b and 14c is set to satisfy the Equation 2. With this setting, the microwaves can be irradiated onto the amorphous silicons present between the electrodes 14b and 14c, crystallize the amorphous silicons into the polysilicons or single crystal silicons at a low temperature, and activate the impurities contained in the amorphous silicons.

A method of manufacturing the ReRAM according to the first embodiment is described next.

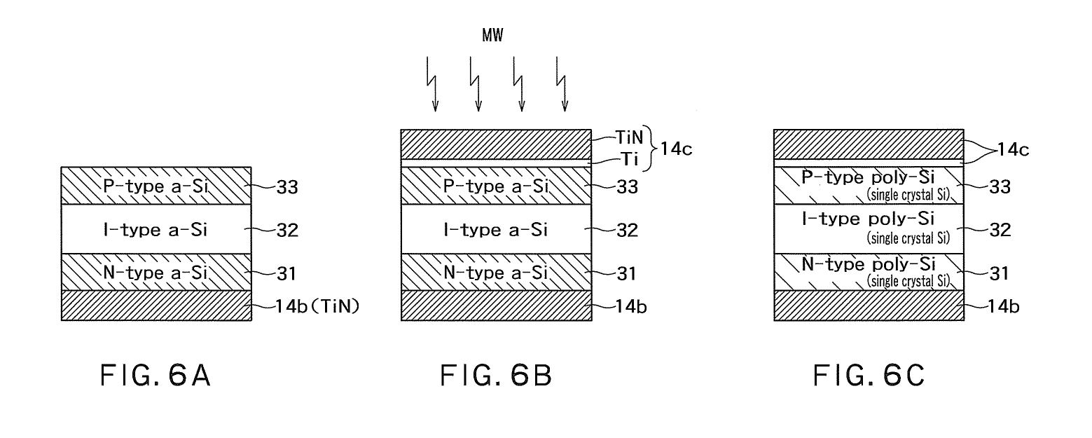

FIGS. 6A to 6G are cross-sectional views showing the method of manufacturing the selector element SD in the ReRAM according to the first embodiment. The peripheral circuit elements and the variable resistive element VR can be formed by a well-known manufacturing method. Therefore, only the method of manufacturing the selector element SD is explained below.

First, after the peripheral circuit elements and the variable resistive element VR are formed on a silicon substrate, the lower electrode 14b is formed above the silicon substrate. The lower electrode 14b is a multilayer film made of tungsten (W) and titanium (Ti), for example. The thicknesses of the tungsten (W) and titanium (Ti) satisfy the Equation 2 described above.

That is, the thicknesses of the tungsten (W) and titanium (Ti) satisfy the following Equation 3.

sqrt(ωμ_{w}σ_{w}/2)×δ_{w}+sqrt(ωμ_{Ti,1}σ_{Ti,1}/2)×δ_{Ti,1}≦1 (Equation 3)

In this equation, μ_{w} represents the magnetic permeability of the tungsten (W), σ_{w} represents the electric conductivity of the tungsten (W), and σ_{w} represents the thickness of the tungsten (W). In addition, μ_{Ti,1} represents the magnetic permeability of the titanium (Ti), σ_{Ti,1} represents the electric conductivity of the titanium (Ti), and δ_{Ti,1} represents the thickness of the titanium (Ti).

Next, the amorphous silicon layer 31 containing an N-impurity and serving as a first semiconductor layer, the intrinsic amorphous silicon layer 32 serving as a second semiconductor layer, and the amorphous silicon layer 33 containing a P-impurity and serving as a third semiconductor layer are sequentially deposited on the lower electrode 14b. More specifically, the amorphous silicon layer 31 containing the N-impurity and having a thickness of about 25 nm is formed at a substrate temperature of about 500° C. using a gas mixture of PH₃/Si₂H₆/He or PH₃/SiH₄/He, for example. Next, the undoped amorphous silicon layer 32 having a thickness of about 50 nm is formed at the substrate temperature of about 500° C. using SiH₄ or Si₂H₆ gas. Furthermore, the amorphous silicon layer 33 containing the P-impurity and having a thickness of about 25 nm is formed at the substrate temperature of about 500° C. using a gas mixture of SiH₃/H₂/BCl₃ or Si₂H₆/H₂/BCl₃, for example. Alternatively, B₂H₆ can be used in place of BCl₃ in a gas mixture of SiH₃/H₂/BCl₃. A PIN multilayer film of the amorphous silicon layers 31 to 33 is thereby formed as shown in FIG. 6A.

Next, as shown in FIG. 6B, the upper electrode 14c is formed on the amorphous silicon layer 33. The upper electrode 14c is a multilayer film made of titanium (Ti) and titanium nitride (TiN), for example. The thicknesses of the titanium (Ti) and the titanium nitride (TiN) satisfy the Equation 2 described above.

That is, the thicknesses of the titanium (Ti) and the titanium nitride (TiN) satisfy the following Equation 4.

sqrt(ωμ_{Ti,2}σ_{Ti,2}/2)×δ_{Ti,2}+sqrt(ωμ_{TiN}σ_{TiN}/2)×δ_{TiN}≦1 (Equation 4)

In this equation, μ_{Ti,2} represents the magnetic permeability of the titanium (Ti), σ_{Ti,2} represents the electric conductivity of the titanium (Ti), and δ_{Ti,2} represents the thickness of the titanium (Ti). In addition, μ_{TiN} represents the magnetic permeability of the titanium nitride (TiN), σ_{TiN} represents the electric conductivity of the titanium nitride (TiN), and δ_{TiN} represents the thickness of the titanium nitride (TiN).

As shown in FIG. 6B, the microwave annealing is performed. More specifically, electromagnetic waves (microwaves MW) at a frequency f (where f ranges from 2.45 GHz to 300 GHz) are irradiated. At this time, the microwaves MW permeate the lower electrode 14b and the upper electrode 14c and reach the amorphous silicon layers 31 to 33 because the lower electrode 14b and the upper electrode 14c satisfy the Equation 2 (and the Equations 3 and 4) described above.

As shown in FIG. 6C, the amorphous silicon layers 31 to 33 are thereby crystallized into the silicon crystal layer 31 containing the N-impurity, the undoped silicon crystal layer 32 in an intrinsic state, and the silicon crystal layer 33 containing the P-impurity, respectively. At this time, the microwave annealing crystallizes the amorphous silicons at a low temperature (200 degrees to 500 degrees) and activates the impurities. Therefore, the impurities in the amorphous silicon layers 31 and 33 do not diffuse so widely into the undoped amorphous silicon layer 32. As a result, the silicon crystal layers 31 to 33 after being irradiated with the microwaves MW can be formed into a desired PIN or NIP structure. That is, according to the first embodiment, the selector element SD having the desired structure can be obtained.

Thereafter, wires (word lines WL) and the like are formed, thus completing the ReRAM according to the first embodiment.

The positions of the silicon crystal layers 31 and 33 can be replaced with each other. In this case, the selector element SD having the NIP structure can be obtained. Moreover, in the first embodiment, the selector element SD is formed out of silicon (Si). Alternatively, germanium (Ge) that belongs to the same Group 14 as the silicon (Si) or an Si—Ge alloy Si₁₋ₓGeₓ (X=0 to 1) can be used to form the selector element SD.

Furthermore, when the frequency of the microwaves is variable, it suffices to determine the angular frequency ω=2πf₀ based on a maximum frequency f₀ among the frequencies of the microwaves used in the microwave annealing. The thicknesses of the lower electrode 14b and the upper electrode 14c can be determined by the Equation 2 using the angular frequency ω₀.

According to the first embodiment, the lower electrode 14b and the upper electrode 14c sandwiching the selector element SD therebetween satisfy the Equation 2 in the microwave annealing step. This enables the microwaves to reach and crystallize the selector element SD. Moreover, the microwaves can activate the impurities contained in the amorphous silicon layers 31 and 33 while suppressing the impurities from diffusing.

According to the first embodiment, the intrinsic silicon crystal layer 32 can be kept thick in the selector element SD. This enables the selector element SD to suppress an off-current.

### Second Embodiment

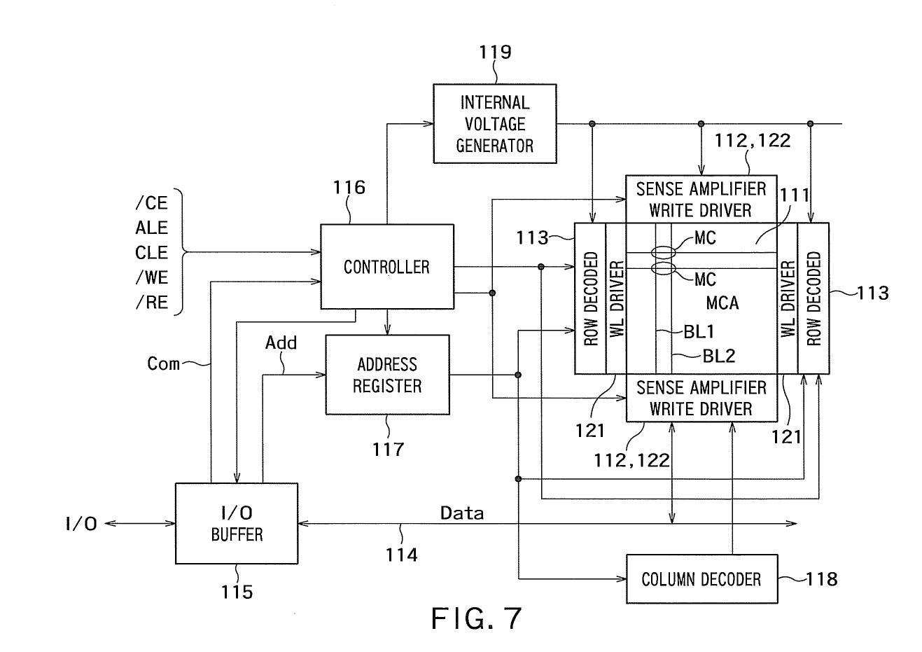

FIG. 7 is a block diagram showing a configuration of an MRAM according to a second embodiment. A plurality of memory cells MC are arranged two-dimensionally in a matrix in a memory cell array 111. Each memory cell MC includes the MTJ element and a cell transistor CT. The MTJ element is a magnetic tunnel junction element that stores therein data by the change in a resistance state and that can rewrite the data by a current. The cell transistor CT is provided to correspond to the MTJ element and configured to become conductive when a current flows to the corresponding MTJ element.

A plurality of word lines WL extend in a row direction and a plurality of bit lines BL extend in a column direction so that the word lines WL cross the bit lines BL. Two adjacent bit lines BL are paired and the memory cells MC are provided to correspond to cross-points between the word lines WL and pairs of bit lines BL (a first bit line BL1 and a second bit line BL2, for example). The MTJ element and the cell transistor CT of each memory cell MC are connected in series between a pair of bit lines (between BL1 and BL2, for example). A gate of the cell transistor CT is connected to one word line WL.

Sense amplifiers 112 and a write driver 122 are arranged on each side of the memory cell array 111 in a bit line direction, that is, the column direction. Each of the sense amplifiers 112 is connected to one bit line BL, and reads data stored in the memory cell MC connected to a selected word line WL by detecting a current flowing to the memory cell MC. Each of the write drivers 122 is connected to the bit lines BL and writes data to the memory cell MC connected to the selected word line WL by carrying a current to the memory cell MC.

A row decoder 113 and a word line driver 121 are arranged on each side of the memory cell array 111 in a word line direction, that is, the row direction. Each word line driver 121 is connected to the word lines WL and configured to apply a voltage to the selected word line WL during a data reading or a writing operation.

Data is transmitted or received between the sense amplifiers 112 or the write drivers 122 and an external input/output terminal I/O via a data bus 114 and an I/O buffer 115.

Various external control signals such as a chip enable signal /CE, an address latch enable signal ALE, a command latch enable signal CLE, a write enable signal /WE, and a read enable signal /RE are input to a controller 116. The controller 116 identifies an address Add and a command Com supplied from the input/output terminal I/O in response to these control signals. The controller 116 then transfers the address Add to the row decoders 113 and the column decoders 118 via an address register 117. In addition, the controller 116 decodes the command Com. Each sense amplifier 112 is configured to be able to apply a voltage to one bit line BL in response to a column address decoded by the column decoder 118. Each of the word line drivers 121 is configured to be able to apply a voltage to the selected word line WL in response to a row address decoded by the row decoder 113.

The controller 116 controls sequences of data reading, data writing, and data erasing in response to the external control signals and the command. An internal voltage generator 119 is provided to generate internal voltages (such as a boosted voltage stepped up from a power supply voltage) necessary for respective operations. The controller 116 also controls this internal voltage generator 119 to perform a voltage boost operation and to generate necessary voltages.

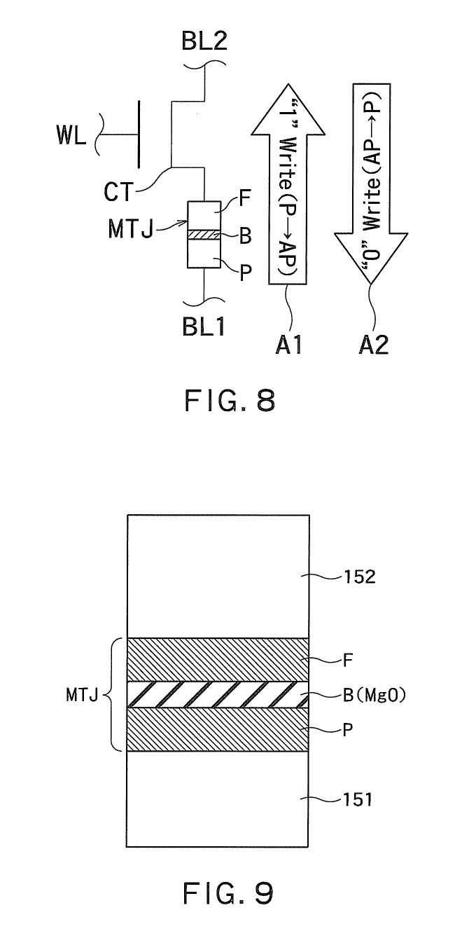

FIG. 8 is an explanatory diagram showing a data writing operation for writing data to one memory cell MC. The MTJ element that uses the TMR effect has a stacked structure in which a nonmagnetic layer (tunnel dielectric film) B is sandwiched between two ferromagnetic layers F and P. The MTJ element stores therein digital data by a change in a magnetic resistance due to the spin-polarized tunneling. The MTJ element can be set in a low resistance state or a high resistance state depending on magnetization orientations of the two ferromagnetic layers F and P. For example, when it is defined that the low resistance state indicates data “0” and that the high resistance state indicates data “1”, one-bit data can be recorded in the MTJ element. Conversely, it can be defined that the low resistance state indicates data “1” and that the high resistance state indicates data “0”.

For example, the MTJ element is configured to sequentially stack the pinned layer P, the tunnel barrier layer B, and the recording layer (free layer) F. The pinned layer P and the free layer F are made of a ferromagnetic body and the tunnel barrier layer B is an insulating film (made of AL₂O₃ or MgO, for example). The pinned layer P has a fixed magnetization orientation. The free layer F has a variable magnetization orientation. The MTJ element stores therein data depending on the magnetization orientation of the free layer F.

During the data writing operation, when an electric field is applied to the MTJ element in an arrow A1 direction, the magnetization orientation of the free layer F becomes anti-parallel (an AP state) to that of the pinned layer P. The MTJ element thereby turns into the high resistance state (data “1”). During the data writing operation, when the electric field is applied to the MTJ element in an arrow A2 direction, the magnetization orientation of the free layer F becomes parallel (a P state) to that of the pinned layer P. The MTJ element thereby turns into the low resistance state (data “0”). In this way, different data can be written to the MTJ element depending on a current flow direction.

FIG. 9 is a cross-sectional view showing a configuration of the MTJ element. The MTJ element includes the tunnel dielectric film B as a crystal layer. In the second embodiment, the tunnel dielectric film B is made of magnesium oxide (MgO) in a polycrystal state. Each of the free layer F and the pinned layer P is made of a magnetic material containing Co, Fe, Ni, Pt, Pd, B, Ta, Dy, Tv, or Cr, for example.

The MTJ element is formed on a lower electrode 151. The lower electrode 151 is electrically connected to diffusion layers of the cell transistor CT shown in FIG. 8 via contacts (not shown). The lower electrode 151 is made of Ta, Pt, Ir, Ru, Pd, W, Ti, Al, one of nitrides thereof, or one of composite materials thereof, for example.

An upper electrode 152 is provided on the MTJ element. The upper electrode 152 is electrically connected to the bit line BL1 or BL2 shown in FIG. 8. The upper electrode 152 is made of Ta, TiAlₓN_{Y}, TaN, WN, W, TiN, or one of composite materials thereof, for example.

The thickness δ of each of the lower electrode 151 and the upper electrode 152 is smaller than the thickness δₛ of the skin layer deriving from the skin effect corresponding to the frequency of microwaves used in the microwave annealing step to be described later (δ≦δₛ). This is a condition in which the microwaves can pass through the lower electrode 151 and the upper electrode 152 and reach the MTJ element present between the lower and upper electrodes 151 and 152. The thickness δ of the lower electrode 151 needs to satisfy the Equation 2 described above, and the thickness δ of the upper electrode 152 also needs to satisfy the Equation 2.

Furthermore, when the free layer F and the pinned layer P shield the microwaves, the thicknesses of the lower electrode 151 and the pinned layer P need to satisfy the Equation 2 and those of the upper electrode 152 and the free layer F also need to satisfy the Equation 2. In this case, similarly to a case where the lower electrode 151 or the upper electrode 152 is made of a plurality of metal materials, it suffices to apply the Equation 2 to the thicknesses. As described above, each of the free layer F and the pinned layer P is made of the ferromagnetic material. When each of the free layer F and the pinned layer P is made of the ferromagnetic material, the magnetic permeability μ of the ferromagnetic material used in the Equation 2 is a maximum value calculated from a magnetization response of the microwaves.

In the second embodiment, the microwave annealing is performed to crystallize the tunnel dielectric film B of the MTJ element. The microwave annealing can sufficiently improve crystallinity at a low temperature. Therefore, the microwave annealing can crystallize the tunnel dielectric film B without degrading characteristics of the lower electrode 151, the upper electrode 152, the pinned layer P, and the free layer F even when the lower electrode 151, the upper electrode 152, the pinned layer P, and the free layer F are made of heat sensitive materials.

As described above, the microwaves are absorbed efficiently by an amorphous material. Accordingly, at a time of forming the tunnel dielectric film B, an insulating film (made of Al₂O₃ or MgO, for example) in an amorphous state is deposited first and the microwaves are irradiated onto this insulating film, thereby crystallizing the insulating film in the amorphous state into an insulating film in a polycrystal state.

The pinned layer P or the free layer F is necessary to use as a seed so as to crystallize the insulating film in the amorphous state into the insulating film in the polycrystal state.

The thicknesses of the lower electrode 151 and the pinned layer P and those of the upper electrode 152 and the free layer F are set to satisfy the Equation 2. The microwaves can be thereby irradiated onto the tunnel dielectric film B in the amorphous state, and crystallize the tunnel dielectric film B in the amorphous state into the tunnel dielectric film B in the polycrystal state at a low temperature, without degrading the pinned layer P and the free layer F.

A method of manufacturing the MRAM according to the second embodiment is described next.

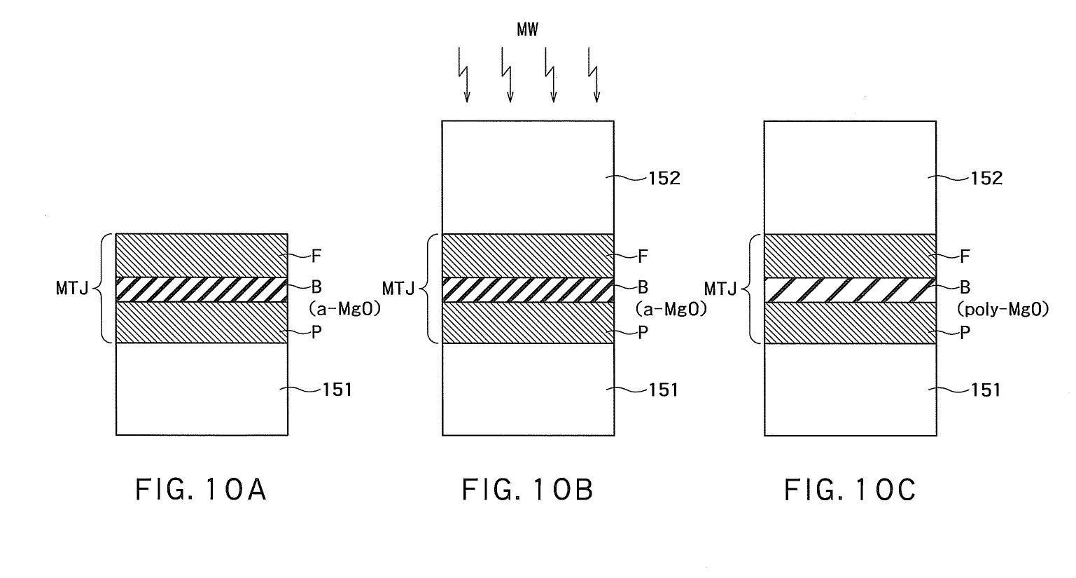

FIGS. 10A to 10C are cross-sectional views showing the method of manufacturing the MRAM according to the second embodiment. The peripheral circuit elements and the cell transistor CT can be formed by a well-known manufacturing method. Therefore, only the method of manufacturing the MTJ element is explained below.

First, the cell transistor CT is formed on a silicon substrate (not shown) and an interlayer dielectric film (not shown) is formed to cover the cell transistor CT with the interlayer dielectric film. The lower electrode 151 is formed on the interlayer dielectric film. The lower electrode 151 is made of titanium nitride (TiN), for example. The thickness of the titanium nitride (TiN) satisfies the Equation 2 described above. Needless to mention, the lower electrode 151 can be made of a plurality of materials.

Next, the MTJ element is formed on the lower electrode 151. For example, materials of the pinned layer P serving as a first ferromagnetic layer, the tunnel dielectric film B in the amorphous state, and the free layer F serving as a second ferromagnetic layer are deposited on the lower electrode 151 in this order. The materials of the free layer F and the pinned layer P are the ferromagnetic materials described above. The material of the tunnel dielectric film B is magnesium oxide (MgO), for example. By processing the materials of the free layer F, the tunnel insulating layer B, and the pinned layer P, the MTJ element is formed on the lower electrode 151 as shown in FIG. 10A.

As shown in FIG. 10B, the upper electrode 152 is formed on the MTJ element. The upper electrode 152 is made of titanium nitride (TiN), for example. The thickness of the titanium nitride (TiN) satisfies the Equation 2 described above.

When the materials of the free layer F and the pinned layer P shield the microwaves, the thicknesses of the lower electrode 151 and the pinned layer P need to satisfy the Equation 2. Further, the thicknesses of the upper electrode 152 and the free layer F also need to satisfy the Equation 2. In this case, similarly to the case where the lower electrode 151 or the upper electrode 152 is made of a plurality of metal materials, it suffices to apply the Equation 2 to the thicknesses.

Next, as shown in FIG. 10B, the microwave annealing is performed. More specifically, the electromagnetic waves (microwaves MW) at the frequency f (where f ranges from 2.45 GHz to 300 GHz) are irradiated. At this time, the microwaves MW permeate the lower electrode 151 and the upper electrode 152 and reach the tunnel dielectric film B of the MTJ element because the lower electrode 151 and the upper electrode 152 (as well as the free layer F and the pinned layer P) satisfy the Equation 2 described above.

As shown in FIG. 10C, the tunnel dielectric film B in the amorphous state is thereby crystallized into the tunnel dielectric film B in the polycrystal state. Therefore, at this time, the microwave annealing is performed at a low temperature (200 degrees to 500 degrees) and can suppress the degradation in the free layer F and the pinned layer P.

Thereafter, the wires (the bit lines BL) and the like are formed, thus completing the MRAM according to the second embodiment. The positions of the free layer F and the pinned layer P can be replaced with each other.

According to the second embodiment, the lower electrode 151 (as well as the pinned layer P) and the upper electrode 152 (as well as the free layer F) sandwiching the tunnel dielectric film B therebetween satisfy the Equation 2 in the microwave annealing step. This configuration enables the microwaves to reach the tunnel dielectric film B and to crystallize the tunnel dielectric film B without degrading the free layer F and the pinned layer P.

According to the second embodiment, the performance of the MRAM can be improved because the tunnel dielectric film B can be crystallized without degrading the free layer F and the pinned layer P.

As described above, the manufacturing method of a semiconductor device according to the first and second embodiments can manufacture semiconductor devices by low-temperature annealing that can improve the crystallinity of a semiconductor material or an insulating film without degrading the characteristics of elements. Furthermore, the semiconductor device according to the first and second embodiments is suitable for such low-temperature annealing.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A semiconductor device comprising:
a lower electrode provided above a semiconductor substrate and made of metal;
an upper electrode provided above the lower electrode and made of metal; and
a crystal layer provided between the lower electrode and the upper electrode, wherein
a thickness of each of the lower electrode and the upper electrode is smaller than a thickness δₛ of a skin layer deriving from a skin effect corresponding to a frequency of a microwave used to crystallize the crystal layer.

2. The device of claim 1, wherein
the thickness δₛ of the skin layer is determined by an Equation 1 as follows:
δₛ=sqrt(2/ωμσ) (Equation 1),
where sqrt means square root, ω(=2πf) represents an angular frequency of the microwave, μ represents a magnetic permeability of the metal constituting each of the lower electrode and the upper electrode, and σ represents an electric conductivity of the metal constituting each of the lower electrode and the upper electrode.

3. The device of claim 2, wherein
when the lower electrode and the upper electrode are made of metal materials M1 to Mn, where n is an integer, thicknesses δ₁ to δₙ of the metal materials M1 to Mn, respectively satisfy an Equation 2 as follows:
sqrt(ωμ₁σ₁/2)×δ₁+sqrt(ωμ₂/2)×δ₂+ . . . sqrt(ωμₙσₙ/2)×δₙ≦1 (Equation 2),
where μ₁ to μₙ represent a magnetic permeability of the metal materials M1 to Mn and σ₁ to σₙ represent an electric conductivity of the metal materials M1 to Mn, respectively.

4. The device of claim 3, wherein
each of the metal materials M1 to Mn comprises a ferromagnetic material, and
a magnetic permeability of the ferromagnetic material is a maximum value calculated from a magnetization response of the microwave.

5. The device of claim 1, wherein
the semiconductor device is a resistance change memory comprising a plurality of memory cells each storing data therein, and
the crystal layer is a PIN diode or an NIP diode provided as a selector element selecting one of the memory cells.

6. The device of claim 1, wherein
the semiconductor device is a resistance change memory comprising a plurality of memory cells each storing data therein,
each of the memory cells comprises a magnetic tunnel junction element which comprises two ferromagnetic layers and a tunnel dielectric film provided between the two ferromagnetic layers, and
the crystal layer is the tunnel dielectric film.

7. A method of manufacturing a semiconductor device, the method comprising:
forming a lower electrode above a semiconductor substrate;
forming an amorphous layer on the lower electrode;
forming an upper electrode on the amorphous layer; and
crystallizing the amorphous layer into a crystal layer by irradiating the amorphous layer with a microwave, wherein
a thickness of each of the lower electrode and the upper electrode is smaller than a thickness of a skin layer deriving from a skin effect corresponding to a frequency of the microwave used to crystallize the crystal layer.

8. The method of claim 7, wherein
the semiconductor device is a resistance change memory comprising a plurality of memory cells each storing data therein,
a first amorphous semiconductor layer containing a first conductive impurity, a second amorphous layer in an intrinsic state, and a third amorphous semiconductor layer containing a second conductive impurity are formed, as the amorphous layer, on the lower electrode in order,
the upper electrode is formed on the third amorphous semiconductor layer,
the first to the third amorphous semiconductor layers are crystallized into first to the third semiconductor crystal layers, respectively by irradiating the first to the third amorphous semiconductor layers with a microwave, and
the first to the third semiconductor crystal layers constitute a PIN diode or an NIP diode provided as a selector element selecting one of the memory cells.

9. The method of claim 7, wherein
the semiconductor device is a resistance change memory comprising a plurality of memory cells each storing data therein, the method comprises:
forming a first ferromagnetic layer on the lower electrode after forming the lower electrode;
forming, as the amorphous layer, a tunnel dielectric film in an amorphous state on the first ferromagnetic layer;
forming a second ferromagnetic layer on the tunnel dielectric film;
forming the upper electrode on the second ferromagnetic layer; and
crystallizing the tunnel dielectric film in an amorphous state into a tunnel dielectric film in a polycrystal state by irradiating the tunnel dielectric film in an amorphous state with a microwave, and
the first and the second ferromagnetic layers and the tunnel dielectric film in a polycrystal state constitute a magnetic junction element comprised by each of the memory cells.

10. The method of claim 7, wherein
the thickness δₛ of the skin layer is determined by an Equation 1 as follows:
δₛ=sqrt(2/ωμσ) (Equation 1),
where sqrt means square root, ω(=2πf) represents an angular frequency of the microwave, μ represents a magnetic permeability of the metal constituting each of the lower electrode and the upper electrode, and σ represents an electric conductivity of the metal constituting each of the lower electrode and the upper electrode.

11. The method of claim 8, wherein
the thickness δₛ of the skin layer is determined by an Equation 1 as follows:
δₛ=sqrt(2/ωμσ) (Equation 1),
where sqrt means square root, ω(=2πf) represents an angular frequency of the microwave, μ represents a magnetic permeability of the metal constituting each of the lower electrode and the upper electrode, and σ represents an electric conductivity of the metal constituting each of the lower electrode and the upper electrode.

12. The method of claim 9, wherein
the thickness δₛ of the skin layer is determined by an Equation 1 as follows:
δₛ=sqrt(2/ωμσ) (Equation 1),
where sqrt means square root, ω(=2πf) represents an angular frequency of the microwave, μ represents a magnetic permeability of the metal constituting each of the lower electrode and the upper electrode, and σ represents an electric conductivity of the metal constituting each of the lower electrode and the upper electrode.

13. The method of claim 10, wherein
when the lower electrode and the upper electrode are made of metal materials M1 to Mn, where n is an integer, thicknesses δ₁ to δₙ of the metal materials M1 to Mn, respectively satisfy an Equation 2 as follows:
sqrt(ωμ₁σ₁/2)×δ₁+sqrt(ωμ₂σ₂/2)×δ₂+ . . . sqrt(ωμₙσₙ/2)×δₙ≦1 (Equation 2),
where μ₁ to μₙ represent a magnetic permeability of the metal materials M1 to Mn and σ₁ to σₙ represent an electric conductivity of the metal materials M1 to Mn, respectively.

14. The method of claim 11, wherein
when the lower electrode and the upper electrode are made of metal materials M1 to Mn, where n is an integer, thicknesses δ₁ to δₙ of the metal materials M1 to Mn, respectively satisfy an Equation 2 as follows:
sqrt(ωμ₁σ₁/2)×δ₁+sqrt(ωμ₂σ₂/2)×δ₂+ . . . sqrt(ωμₙσₙ/2)×δₙ≦1 (Equation 2),
where μ₁ to μₙ represent a magnetic permeability of the metal materials M1 to Mn and σ₁ to σₙ represent an electric conductivity of the metal materials M1 to Mn, respectively.

15. The method of claim 12, wherein
when the lower electrode and the upper electrode are made of metal materials M1 to Mn, where n is an integer, thicknesses δ₁ to δₙ of the metal materials M1 to Mn, respectively satisfy an Equation 2 as follows:
sqrt(ωμ₁σ₁)×δ₁+sqrt(ωμ₂σ₂/2)×δ₂+ . . . sqrt(ωμₙσₙ/2)×δₙ≦1 (Equation 2),
where μ₁ to μₙ represent a magnetic permeability of the metal materials M1 to Mn and σ₁ to σₙ represent an electric conductivity of the metal materials M1 to Mn, respectively.

16. The device of claim 13, wherein
each of the metal materials M1 to Mn comprises a ferromagnetic material, and
a magnetic permeability of the ferromagnetic material is a maximum value calculated from a magnetization response of the microwave.

17. The device of claim 14, wherein
each of the metal materials M1 to Mn comprises a ferromagnetic material, and
a magnetic permeability of the ferromagnetic material is a maximum value calculated from a magnetization response of the microwave.

18. The device of claim 15, wherein
each of the metal materials M1 to Mn comprises a ferromagnetic material, and
a magnetic permeability of the ferromagnetic material is a maximum value calculated from a magnetization response of the microwave.
